(19) United States
(12) Patent Application Publication
(10) Pub. No.: US 2014/0021486 A1
(43) Pub. Date: Jan. 23, 2014

(54) LIGHT EMITTING DIODE AND MANUFACTURING METHOD THEREOF

(71) Applicant: ADVANCED OPTOELECTRONIC TECHNOLOGY, INC., Hsinchu Hsien (TW)

(72) Inventors: YA-WEN LIN, Hsinchu (TW); SHIH-CHENG HUANG, Hsinchu (TW); PO-MIN TU, Hsinchu (TW)

(21) Appl. No.: 13/907,988

(22) Filed: Jun. 3, 2013

(30) Foreign Application Priority Data
Jul. 17, 2012 (CN) 2012102466524

(51) Int. Cl. H01L 33/32; H01L 33/00

(52) U.S. Cl. CPC H01L 33/32; H01L 33/0075
USPC 257/77; 257/76; 438/47

(57) ABSTRACT

A light emitting diode (LED) includes a substrate and an eputaxial layer on the substrate. The epitaxial layer includes a N-type GaN-based layer, a light emitting layer, and a P-type GaN-based layer. The LED further includes a first electrode on the N-type GaN-based layer and a second electrode on the P-type GaN-based layer. The P-type GaN-based layer has a inactive portion, and the second electrode is located and covers the inactive portion.

### BACKGROUND

1. Technical Field

The disclosure relates to light emitting diodes and manufacturing methods thereof, and more particularly to a light emitting diode which has uniform light output and a manufacturing method thereof.

2. Description of Related Art

Light emitting diodes (LEDs) have been widely promoted as a light source of electronic devices owing to many advantages, such as low power consumption, high efficiency, quick reaction time and long lifetime.

A conventional LED includes a substrate, a semiconductor light emitting structure formed on the substrate and a P-type electrode and an N-type electrode formed on the semiconductor light emitting structure. However, in operation, current of the LED is easy to gather around the P-type electrode and the N-type electrode, the brightness adjacent the two electrodes is highest, so the light output of the LED is not uniform. Furthermore, the heat is easy to gather around the two electrodes, the temperature adjacent the two electrodes is too high and would damage the LED.

Therefore, an LED and a manufacturing method thereof that overcome aforementioned deficiencies are required.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 shows a cross-sectional view of an LED in accordance with an embodiment of the present disclosure.

FIGS. 2-7 are schematic, cross-sectional views showing steps of a method for manufacturing the LED of FIG. 1.

### DETAILED DESCRIPTION

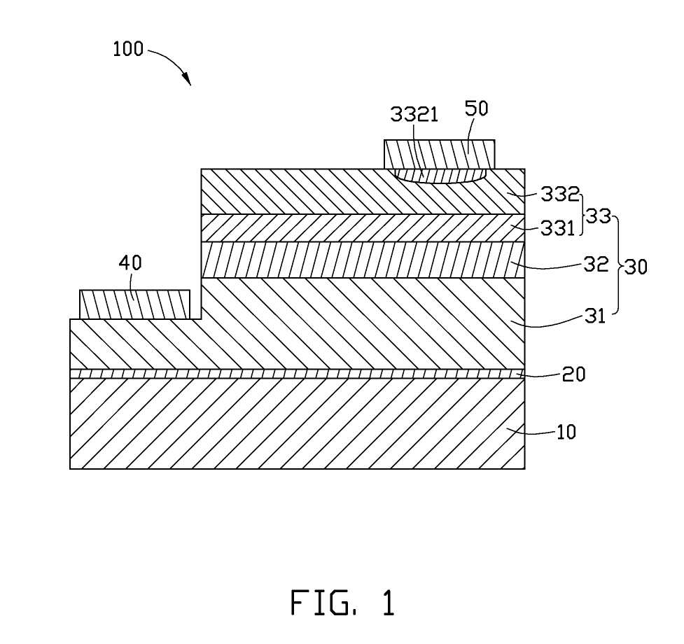

Referring to FIG. 1, an LED 100 in accordance with a first embodiment of the present disclosure includes a substrate 10, a buffer layer 20 disposed on the substrate 10 and an epitaxial layer 30 disposed on the buffer layer 20.

The substrate 10 is made of sapphire (Al₂O₃). Alternatively, the substrate 10 also can be made of silicon carbide (SiC), silicon or gallium nitride (GaN).

The buffer layer 20 is disposed on a surface of the substrate 10, by which, deficiencies formed in the epitaxial layer 30 due to lattice mismatch can be reduced. For the same reason, lattice constants of the buffer layer 20 are close to lattice constants of the epitaxial layer 30. In the embodiment, the buffer layer 20 is made of un-doped GaN.

The epitaxial layer 30 comprises a first semiconductor layer 31, a light emitting layer 32 and a second semiconductor 33 sequentially disposed on the buffer layer 20. In the embodiment, the first semiconductor layer 31 is an N-type GaN-based layer, the light emitting layer 32 is a multiple quantum well (MQW) AlₓIn_{y}Ga_{1-x-y}N/Al_{w}InₜGa_{1-w-t}N layer, wherein 1≧x≧0, 1≧y≧0, 1≧w≧0, 1≧t≧0 and the second semiconductor layer 33 is a P-type GaN-based layer. Moreover, the second semiconductor layer 33 includes a P-type blocking layer 331 on the light emitting layer 32 and a P-type contacting layer 332 on the P-type blocking layer 331. Furthermore, the P-type blocking layer 331 can be composed of P-type aluminum gallium nitride (AlGaN), and the P-type contacting layer 332 can be composed of P-type GaN. When electrons inside the first semiconductor layer 31 and holes inside the second semiconductor layer 33 are recombination, photons are emitted from the light emitting layer 32. An inactive portion 3321 is formed in the P-type contacting layer 332. The inactive portion 3321 is surrounded by the other part of the P-type contacting layer 332. In this embodiment, the inactive portion 3321 has a characteristic of high resistance.

The LED 100 further includes a first electrode 40 and a second electrode 50 formed on the epitaxial layer 30. The first electrode 40 is formed on an exposed portion of the first semiconductor layer 31. The second electrode 50 is formed on the top surface of the inactive portion 3321 and covers the inactive portion 3321. In this embodiment, the second electrode 50 contacts the top surface of the inactive portion 3321. The first and second electrodes 40, 50 are formed by the vacuum evaporation or sputtering method.

For the inactive portion 3321 which has a characteristic of high resistance being formed on the top portion of the P-type contacting layer 332, the second electrode 50 being formed on the top surface of the inactive portion 3321 and covering the inactive portion 3321. Due to the high resistance issue, the current is difficult to directly flow through the inactive portion 3321. As a result, the current will flow to other ways around the inactive portion 3321, so the current is diffused evenly whereby causes the light output from the LED 100 can be uniform. Furthermore, the heat generated by the LED 100 do not gather around the short cut between the first electrode 40 and the second electrode 50, whereby improves the lifetime of the LED 100.

A manufacturing method for the LED 100 of the present disclosure comprises following steps:

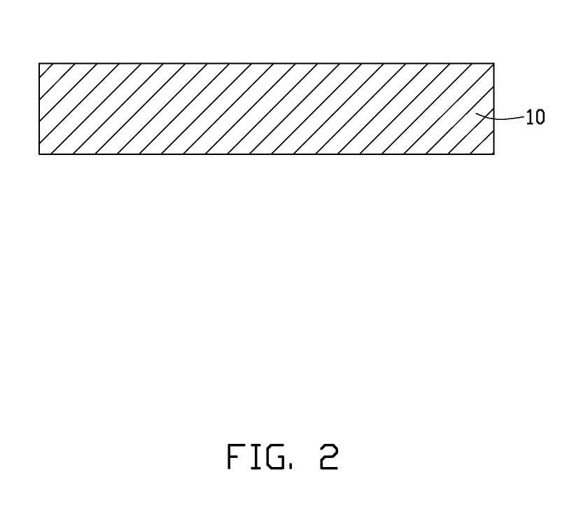

As shown in FIG. 2, a substrate 10 is provided. The substrate 10 is made of sapphire (Al₂O₃). Alternatively, the substrate 10 also can be made of silicon carbide (SiC), silicon or gallium nitride (GaN).

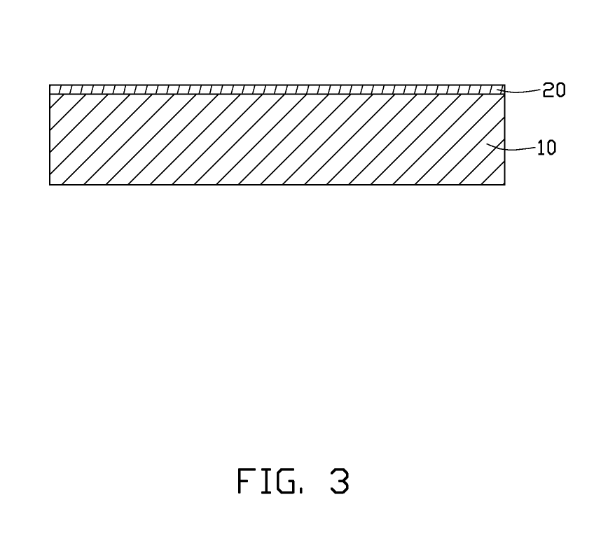

As shown in FIG. 3, a buffer layer 20 is formed on the substrate 10. In the embodiment, the buffer layer 20 is made of un-doped GaN.

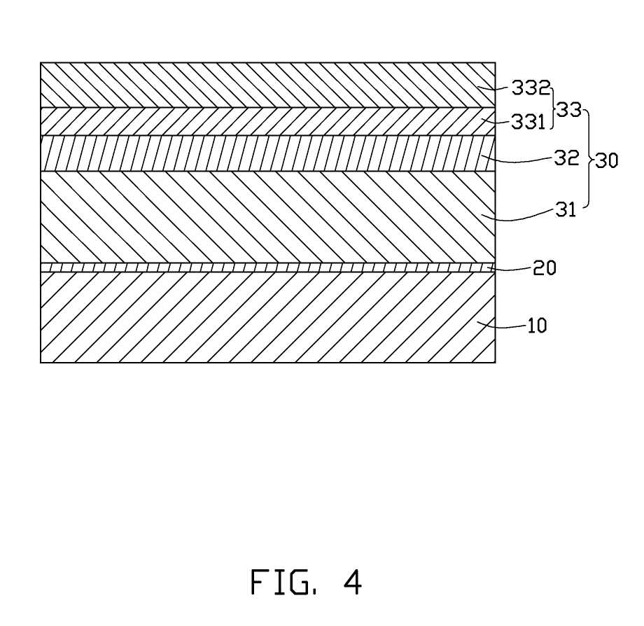

Referring to FIG. 4, an epitaxial layer 30 is formed on the buffer layer 20, wherein the epitaxial layer 30 sequentially includes a first semiconductor layer 31, a light emitting layer 32, and a second semiconductor layer 33. The epitaxial layer 30 can be formed by MOCVD, MBE, or HYPE. The light emitting layer 32 and the second semiconductor layer 33 are located on the top surface of the first semiconductor layer 31. In the embodiment, the epitaxial layer 30 can be made of GaN-based, wherein the first semiconductor layer 31 is an N-type GaN-based layer, the light emitting layer 32 is a MQW AlₓIn_{y}Ga_{1-x-y}N/Al_{w}InₜGa_{1-w-t}N layer, wherein 1≧x≧0, 1≧y≧0, 1≧w≧0, 1≧t≧0, the second semiconductor layer 33 is a P-type GaN-based layer. The second semiconductor layer 33 further includes a P-type blocking layer 331 on the light emitting layer 32 and a P-type contacting layer 332 on the P-type blocking layer 331. In the embodiment, the P-type blocking layer 331 is made of AlGaN, and the P-type contacting layer 332 is made of GaN.

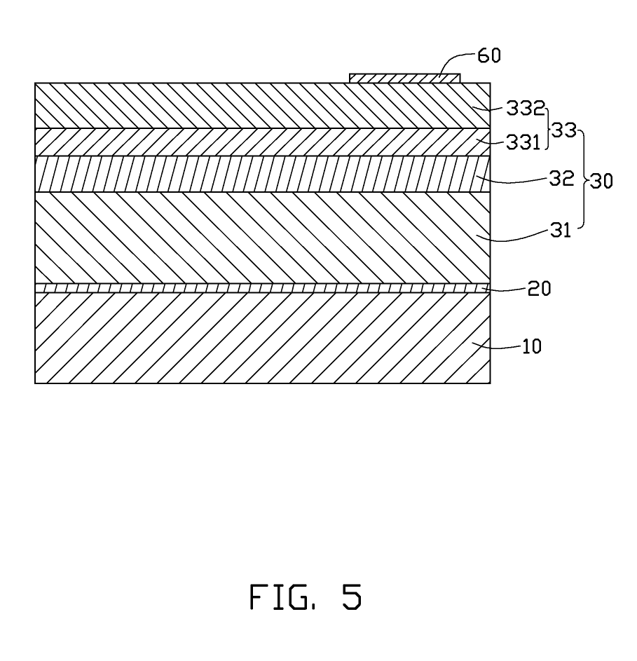

Referring to FIG. 5, a shielding layer 60 is provided on a top surface of the P-type contacting layer 332, and the shielding layer 60 covers part of the P-type contacting layer 332 which is located on the position of the second electrode. The shielding layer 60 is made of electrical insulating material with high temperature endurance or metal material, such as SiO₂. Moreover, a shape of the shielding layer 60 is as the same as the second electrode, and a size of the shielding layer 60 is smaller than the second electrode.

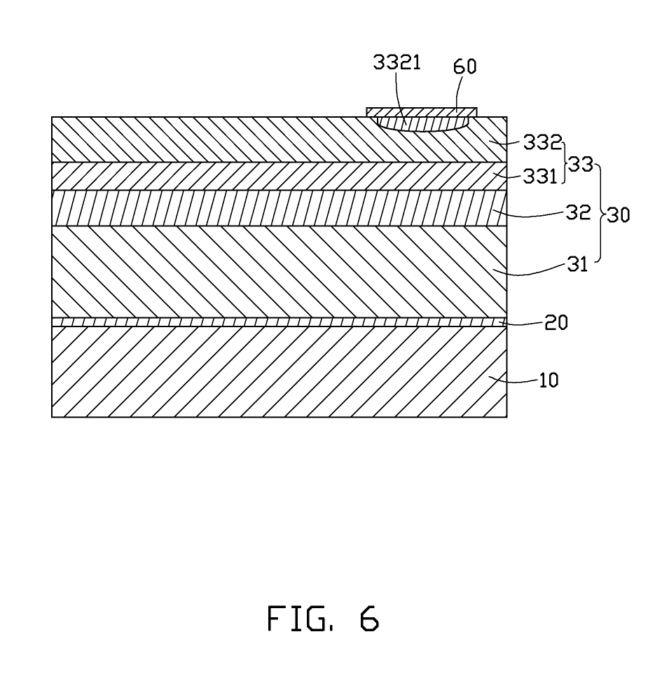

Referring to FIG. 6, through an activation treatment in high temperature for 20-30 min, the portion of the P-type contacting layer 332 which under the shielding layer 60 is not activated, so an inactive portion 3321 is formed. The inactive portion 3321 is surrounded by the other part of the P-type contacting layer 332. The inactive portion 3321 has a top surface coplanar with the top surface of the P-type contacting layer 332, and the inactive portion 3321 has a characteristic of high resistance.

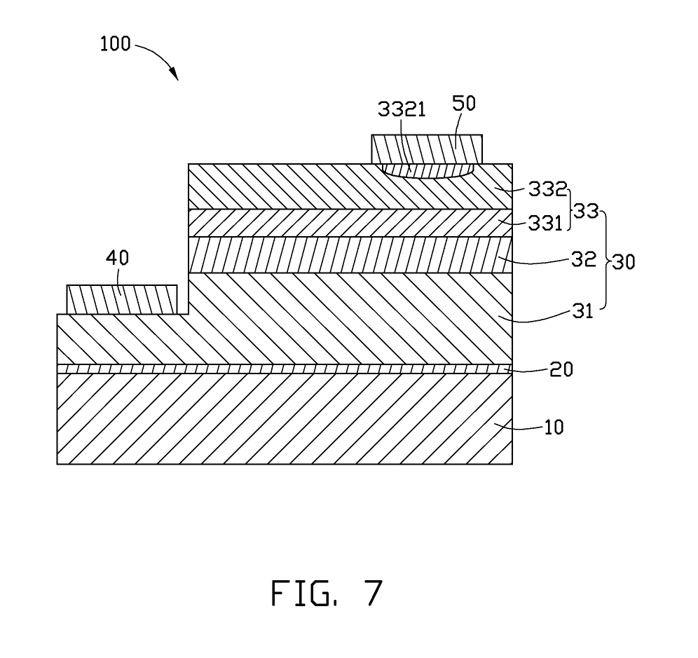

Referring to FIG. 7, the shielding layer 60 is removed first, and then the epitaxial layer 30 processed by chip procedure. A first electrode 40 is formed on the first semiconductor layer 31, and a second electrode 50 is formed on the top surface of the inactive portion 3321 and covers the inactive portion 3321. The second electrode 50 contacts the top surface of the inactive portion 3321. The first and second electrodes 40, 50 are formed by the vacuum evaporation or sputtering method. The first electrode 40 and second electrode 50 can be made of titanium, aluminum, silver, nickel, tungsten, copper, palladium, chromium, gold or an alloy thereof.

When two ends of the first electrode 40 and second electrode 50 are applied a positive current, electrons inside the first semiconductor layer 31 and holes inside the second semiconductor layer 33 are recombination, photons are emitted from the light emitting layer 32. For the inactive portion 3321 which has a characteristic of high resistance being formed on the P-type contacting layer 332, the second electrode 50 being formed on the top surface of the inactive portion 3321 and covering the inactive portion 3321, the current streams difficultly when it flows under the second electrode 50, then flows to other ways around the inactive portion 3321, so the current is diffused evenly whereby causes the light output from the LED 100 can be uniform. Furthermore, the heat generated by the LED 100 do not gather around the short cut between the first electrode 40 and the second electrode 50, whereby improves the lifetime of the LED 100.

Particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A light emitting diode (LED), comprising:
a substrate;
an epitaxial layer on the substrate, wherein the epitaxial layer comprising a N-type GaN-based layer, a light emitting layer, and a P-type GaN-based layer;
a first electrode on the N-type GaN-based layer; and
a second electrode on the P-type GaN-based layer;
wherein the P-type GaN-based layer having a inactive portion, the second electrode located and covers the inactive portion.

2. The light emitting diode of claim 1, further comprising a buffer layer located between the epitaxial layer and the substrate.

3. The light emitting diode of claim 1, wherein the substrate is made of sapphire (Al₂O₃), silicon carbide (SiC), silicon or gallium nitride (GaN).

4. The light emitting diode of claim 1, wherein the P-type GaN-based layer comprises a P-type blocking layer on the light emitting layer and a P-type contacting layer on the P-type blocking layer, the inactive portion is formed on a portion of the P-type contacting layer, and the inactive portion has a surface coplanar with a top surface of the P-type contacting layer.

5. The light emitting diode of claim 1, wherein a shape of the shielding layer is as the same as the second electrode, and a size of the shielding layer is smaller than the second electrode.

6. The light emitting diode of claim 1, wherein the inactive portion has a characteristic of high resistance.

7. A method for manufacturing an LED, comprising steps of:
providing a substrate;
forming a buffer layer on the substrate;
forming an epitaxial layer on the buffer layer, the epitaxial layer sequentially comprising a N-type GaN-based layer, a light emitting layer and a P-type GaN-based layer;
providing a shielding layer on a top surface of the P-type GaN-based layer, the shielding layer covering part of the P-type GaN-based layer;
activating the P-type GaN-based layer, so an inactive portion being formed under the shielding layer;
removing the shielding layer;
processing a chip procedure, a first electrode on the N-type GaN-based layer, and a second electrode to cover a top surface of the inactive portion of the P-type GaN-based layer.

8. The method for manufacturing an LED of claim 7, wherein the P-type GaN-based layer comprises a P-type blocking layer on the light emitting layer and a P-type contacting layer on the P-type blocking layer, the inactive portion is formed on a top portion of the P-type contacting layer, and the inactive portion is coplanar with the P-type contacting layer.

9. The method for manufacturing an LED of claim 7, wherein a shape of the shielding layer is as the same as the second electrode, and a size of the shielding layer is smaller than the second electrode.

10. The method for manufacturing an LED of claim 7, wherein the shielding layer is made of electrical insulating material with high temperature resistance, such as SiO2.

11. The method for manufacturing an LED of claim 7, wherein the inactive portion has a characteristic of high resistance.
